(19) United States
(12) Patent Application Publication
(10) Pub. No.: US 2003/0071661 A1
(43) Pub. Date: Apr. 17, 2003

(54) Input circuit

(76) Inventor: Fumio Eguchi, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/222,923

(22) Filed: Aug. 19, 2002

(30) Foreign Application Priority Data
Oct. 15, 2001 (JP) 316814/2001

(51) Int. Cl. H03B 1/00

(52) U.S. Cl. 327/108

(57) ABSTRACT

In order to obtain an input circuit capable of guaranteeing sufficient threshold margins even if a different power supply potential is supplied, an input circuit relating to the present invention comprises an inverter, an NMOS transistor, and a threshold circuit. The inverter receives, inverts, and outputs an IN signal. The NMOS transistor is connected across the inverter and an earth potential node, and a conductive state is controlled by a control signal generated from the threshold circuit. The threshold circuit generates the control signal for controlling a threshold of the inverter.

### BACKGROUND OF THE INVENTION

1. Field of the Invention

The present invention relates to an input circuit of a semiconductor device, and more particularly relates to an input circuit of a semiconductor device for inverting and outputting a received signal.

2. Description of Related Art

FIG. 10 shows an example of an input circuit of the related art. A related input circuit comprises an inverter INV1, a power supply potential node T1, and an earth potential node T2 (also referred to as a reference potential node T2). The inverter INV1 comprises a P channel MOS transistor (hereafter referred to as PMOS) 101, an N channel MOS transistor (hereafter referred to as NMOS) 103, an input node 105, and an output node 107. The gate (a gate is defined as a control electrode at the MOS transistor) of PMOS 101 is connected to the input node 105, the source is connected to the power supply potential node T1, and the drain is connected to the output node 107. The power supply potential node T1 is supplied with a power supply potential VDD. The power supply potential VDD is, for example, 5V. The earth potential node T2 is supplied with an earth potential GND. The earth potential GND is, for example, 0V.

In the input circuit configured in this manner, PMOS 101 is turned off, NMOS 103 is turned on, and an OUT signal at a second logic level is outputted when an IN signal at a first logic level is received. Here, the first logic level is a high level (hereafter referred to as “H”) and has a 5V potential. Also, the second logic level is a low level (hereafter referred to as (“L”) and has a 0V potential.

In addition, in the input circuit, PMOS 101 is turned on, NMOS 103 is turned off, and an OUT signal at the first logic level or the “H” OUT signal is outputted when an IN signal at the second logic level or the “L” IN signal is received.

In other words, the related input circuit has a function for outputting either an “L” or “H” OUT signal inverted from this IN signal based on an IN signal applied to the input node 105.

However, in the related input circuit, a threshold is set by a W/L (where W represents a gate width and L represents a gate length. Hereafter referred to as a “dimension”.) of PMOS 101 and NMOS 103 fixed at the time of circuit design. Therefore, there is a problem that a dimension of PMOS 101 or NMOS 103 has to be modified in order to change the threshold.

In order to describe the problem that modification of a dimension is required, a “threshold” will first be described. A threshold is a reference value for determining whether an input signal applied to an inverter is “H” or “L” and is a potential value where an input potential and an output potential become equal. The threshold is generally set to half of a power supply potential VDD so that a threshold margin of an inverter is fully secured.

Next, a threshold margin will be described. FIG. 11 is a graph showing an input/output characteristic of an inverter. The horizontal axis of the graph represents an input potential of the inverter and the vertical axis of the graph represents an output potential of the inverter In this example, the power supply potential VDD is 5V. When the input potential is 0V, the output potential is 5V Thereafter, the output potential will be changed to 0V based on the 2.5V (the threshold of the inverter) of the input potential. A case where a maximum value of an “L” IN signal (hereafter the maximum value of the “L” input signal is referred to as “VIL”) is set to 1.5V (the power supply potential VDD×0.3), and a minimum value of an “H” IN signal (hereafter the minimum value of the “H” level signal is referred to as “VIH”) is set to 3.5V (the power supply potential VDD×0.7) will be described. The threshold margin consists of an “L” side threshold margin and an “H” side threshold margin. The threshold margin on the “L” side is in a range from VIL (1.5V) to the threshold (2.5V) of the inverter at the input potential (shown as margin L in the graph). On the hand, the threshold margin on the “H” side is in a range from the threshold (2.5V) of the inverter to VIH (3.5V) at the input potential (shown as margin H in the graph).

For example, if a power supply potential VDD of 3V is provided to the input circuit designed to a 5V specification to use 5V as a power supply potential VDD, there is a danger of the threshold margin of the input circuit decreasing.

This decrease of the threshold margin will be described using FIG. 12. FIG. 12 (a) shows a threshold margin when a 5V specification input circuit is used with a power supply potential VDD=5V, and FIG. 12(b) and (c) show a threshold margin when a 5V specification input circuit is used with a power supply potential VDD=3V.

Since in a 5V specification input circuit a threshold is generally set to 2.5V, both threshold margins at the “H” side and the “L” side can be fully secured (FIG. 3(a)) when this input circuit is used under a condition of power supply potential VDD=5V. On the other hand, when the input circuit is used with the power supply potential VDD=3V, when VIL is set to 0.9V (the power supply potential VDD×0.3) and VIH is set to 2.1V (the power supply potential VDD×0.7), it is preferable to set the threshold to 1.5V in order to fully secure both the threshold margins on the “H” side and the “L” side. However, the threshold does not necessarily become 1.5V, and sometimes the threshold becomes higher than 1.5V (FIG. 3(b)) while at other times the threshold becomes lower than 1.5V (FIG. 3(c)) when a 5V specification input circuit is used with the power supply potential VDD=3V. When the threshold is higher than 1.5V, the threshold margin on the “H” side decreases, while on the other hand, when the threshold is lower than 1.5V, the threshold margin on the “L” side decreases.

In this way, because in the related input circuit a threshold is set according to a dimension of a transistor fixed at the time of circuit design, there is a danger of either a margin at the “H” side or a margin at the “L” side decreasing when the input circuit is operated under a different power supply potential. As a result, when there is noise on a power supply potential and an earth (reference) potential, there is a possibility of outputting a wrong OUT signal as a result of the noise exceeding the threshold of the inverter INV1.

### SUMMARY OF THE INVENTION

An input circuit of the present invention sets out to solve the above problems, and a typical input circuit comprises a power supply potential node a reference potential node, a first node, an inverter, and a transistor. The inverter is connected across the power supply potential node and the first node. The transistor is connected across the first node and the reference potential node and controlled by a control signal outputted from a threshold circuit. The threshold circuit outputs a control signal for controlling the threshold of the inverter.

### BRIEF DESCRIPTION OF THE DRAWINGS

FIG. 1 is a circuit diagram showing a configuration of an input circuit for the first embodiment of the present invention

FIG. 2 is a circuit diagram showing a configuration of a threshold circuit shown in FIG. 1

FIG. 3 is an input/output waveform diagram of an input circuit generated by a circuit simulation

FIG. 4 is a circuit diagram showing a configuration of an input circuit for the second embodiment of the present invention

FIG. 5 is a circuit diagram showing a configuration of a threshold circuit shown in FIG. 4

FIG. 6 is a circuit diagram showing a configuration of an input circuit for the third embodiment of the present invention

FIG. 7 is a circuit diagram showing a configuration of an operational amplifier shown in FIG. 7

FIG. 8 is a circuit diagram showing a configuration of an input circuit for the fourth embodiment of the present invention.

FIG. 9 is a circuit diagram showing a configuration of an operational amplifier shown in FIG. 8.

FIG. 10 is a circuit diagram of an input circuit of the related art.

FIG. 11 is a graph showing an input/output characteristic of the inverter.

FIG. 12 are drawings for describing decrease of threshold margins.

### DETAILED DESCRIPTION OF THE PREFERRED EMBODIMENTS

First Embodiment

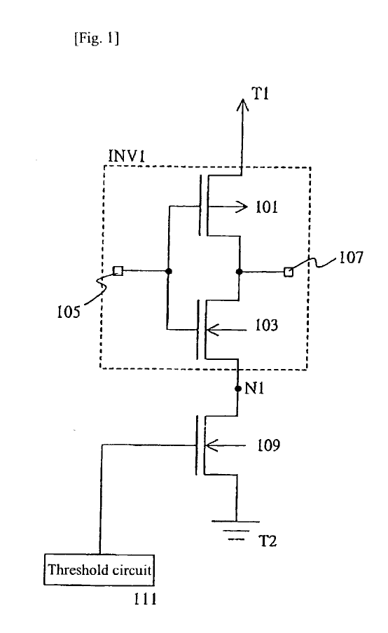

The following is a description of an embodiment of the present invention with reference to the drawings. The same symbol will be used in the following as for the previously described parts of the related input circuit in FIG. 1.

FIG. 1 is a circuit diagram showing an input circuit of the first embodiment. The input circuit of the present invention comprises a power supply potential node T1, an earth potential node T2 (or it is also referred to as a reference potential node T2), a node N1, a complementary type (CMOS) inverter INV1 for receiving, inverting and outputting a signal, an N channel type MOS transistor (hereafter referred to as NMOS) 109 constituting a switch circuit for conducting between the node N1 and the earth potential node T2 in response to a control signal, and the threshold circuit 111 for detecting a power supply potential VDD and for outputting the control signal.

The power supply potential node T1 is supplied with the power supply potential VDD. The power supply potential VDD is 5V or 3V in this embodiment. The earth potential node T2 is supplied with a reference potential taken as a reference. An earth potential GND is used for the reference potential in this case. The earth potential GND is, for example, 0V.

The inverter INV1 comprises a first conduction type and a second conduction type MOS transistors 101, with a P channel type MOS transistor being used here (hereafter referred to as PMOS), an NMOS 103, an input node 105, and an output node 107. A gate (a gate is defined as a control electrode at the MOS transistor) of the PMOS 101 is connected to the input node 105, a source is connected to the power supply potential node T1, and a drain is connected to the output node T2. A gate of the NMOS 103 is connected to the input node 105, a source is connected to the earth potential node T2, and a drain is connected to the output node 107.

A source of the NMOS 109 is connected to the earth potential node T2, and a drain is connected to the node N1. The threshold circuit 111 is connected to the gate of the NMOS 109.

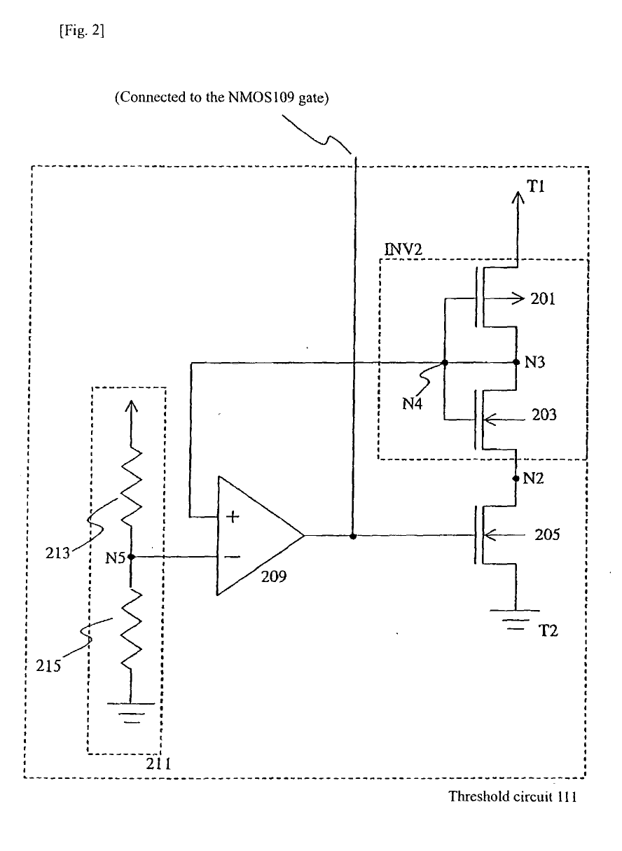

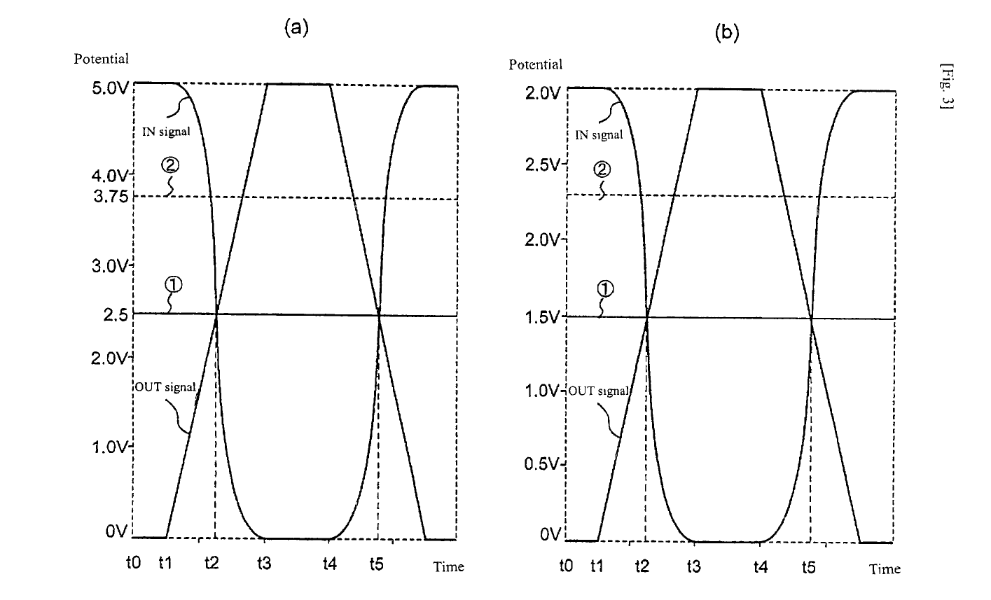

Next, the threshold circuit 111 of FIG. 1 will be described with reference to a circuit diagram of FIG. 2. The threshold circuit 111 comprises a power supply potential node T1, an earth potential node T2, a node N2, an inverter INV2 (although this is referred to as an inverter INV2, it does not actually have a function for inverting a signal since input/output is short-circuited), an NMOS 205, a control circuit 209 (an operational amplifier is used for the control circuit in this embodiment), and a reference potential generating circuit 211 for generating a reference potential.

The inverter INV2 comprises a PMOS 201, an NMOS 203, a node N3 and a node N4. With the PMOS 201, a gate is connected to the node N4, a source is connected to the power supply potential node T1, and a drain is connected to the node N3. With the NMOS 203, a gate is connected to the node N4, a source is connected to the node N2, and a drain is connected to the node N3. The node N4 and the node N3 constituting an input/output node of the inverter INV2 are short-circuited together, and saturation currents I201 and I203 flow to the PMOS 201 and the NMOS 203 respectively. The potential of the node N4 becomes a threshold of the inverter when these saturation currents I201 and I203 are balanced. With the NMOS 205 a source is connected to the earth potential node T2, and a drain is connected to the node N2. A ratio of a dimension (where “dimension” refers to the ratio W/L of a MOS transistor, where W represents a gate width and L represents a gate length) of the PMOS 201, a dimension of the NMOS 203, and a dimension of the NMOS 205 is set equal to a ratio of a dimension of the PMOS 101, a dimension of the NMOS 103, and a dimension of the NMOS 109. For example, (PMOS 201 dimension):(NMOS 203 dimension):(NMOS 205 dimension)=(PMOS 101 dimension):(NMOS 103 dimension):(NMOS 109 dimension)=2:3:4. By being set in this manner, (an ON resistance value of the PMOS 201):(an ON resistance value of the NMOS 203):(an ON resistance value of the NMOS 205) becomes equal to (an ON resistance value of the PMOS 101):(an ON resistance value of the NMOS 103):(an ON resistance value of the NMOS 109) when the same control signal is supplied to the gate of the NMOS 205 and the gate of the NMOS 109. Namely, by setting in this manner, (the ON resistance value of the PMOS 201):(the total of the ON resistance value of the NMOS 203 and the ON resistance value of the NMOS 205) becomes equal to (the ON resistance value of the PMOS 101):(the total of the ON resistance value of the NMOS 103 and the ON resistance value of the NMOS 109), and a threshold of the inverter INV2 becomes equal to a threshold of the inverter INV1. By setting (the ON resistance value of the PMOS 201): (the total of the ON resistance value of the NMOS 203 and the ON resistance value of the NMOS 205)=(the ON resistance value of the PMOS 101):(the total of the ON ,resistance value of the NMOS 103 and the ON resistance value of the MOS 109) to substantially 1:1, the threshold of the inverter INV2 and the threshold of the inverter INV1 become approximately half of the power supply potential VDD. A ratio of substantially 1:1 exhibits the effective range of the present invention. Therefore, ratios such as 1.1:0.9 are by no means excluded. In this embodiment, the dimension (W/L) of the PMOS 101 is set to 40 μm/2 μm, the NMOS 103 is set to 60 μm/2 μm, the NMOS 401 is set to 80 μm/2 μm, the dimension of the PMOS 201 is set to 20 μm/2 μm, the NMOS 203 to 30 μm/2 μm, and the NMOS 205 is set to 4 μm/2 μm. In the operational amplifier 209, a non-inverting input terminal (+) is connected to the node N4, an inverting input terminal (−) is connected to the reference potential generating circuit 211, and an output terminal is connected to the gate of the NMOS 205 and the gate of the NMOS 109. The reference potential generating circuit 211 is, for example, a voltage divider circuit comprising a plurality of resistive elements connected in series. In FIG. 2, resistive elements 213 and 215 are connected in series, with an end connected in common being a node N5. The resistance of the resistive elements 213 and 215 is set to 200 kΩ in this embodiment. The node N5 is connected to the non-inverting input terminal of the operational amplifier 209.

Next, the operation will be described. First, a case that 5V is used for a power supply potential VDD is described.

When 5V is used for the power supply potential VDD, a threshold of the inverter INV1 is preferably set to 2.5V. This is because it is necessary to fully secure both a margin at the “H” side and a margin at the “L” side. When 5V is used for the power supply potential VDD, VIH is set to 3.5V (power supply potential VDD×0.7) and VIL is set to 1.5V (power supply potential VDD×0.3). As a result, these both margins can be fully secured when a threshold potential is set to 2.5V constituting an intermediate value between the VIH (3.5V) and the VIL (1.5V). Therefore, 2.5V of a reference potential is set for the reference potential generating circuit 211.

In the circuit diagram of FIG. 2, the resistive elements 213 and 215 constituting the reference potential generating circuit 211 are both set to 200 k Ω. Since the power supply potential node T1 is supplied with 5V of the power supply potential VDD and the earth potential node T2 is supplied with the 0V of the earth potential GND, 2.5V of the reference potential is outputted from the reference potential generating circuit 211.

At the operational amplifier 209, 2.5V of the reference potential outputted from the reference potential generating circuit 211 is received at the inverting input terminal (−) the potential of the node N4 is received at the non-inverting input terminal (+), and the compared results are outputted to the NMOS 205. In the circuit configuration of FIG. 2, when the potential of the node N5 is 2.5V, the operational amplifier 209 outputs a control signal to the NMOS 205 so that the potential of the node N4 becomes also 2.5V.

This operation is further described in detail. The node N4 and the node N3 constituting an input/output node of the inverter INV2 are short-circuited together, and saturation currents I201 and I203 respectively flow to the PMOS 201 and the NMOS 203 constituting the inverter INV2. The potential of the node N4 becomes a threshold of the inverter when these saturation currents I201 and I203 are balanced. At this time, since the saturation current I203 flowing in the NMOS 203 that constitutes the inverter INV2 flows into the NMOS 205, the saturation current I203 becomes equal to a current I205 flowing into the NMOS 205. Therefore, the threshold of the inverter is determined by the current I205 flowing into the NMOS 205, and the current I205 is determined by a voltage across the gate and the source of NMOS 205. The gate potential of NMOS 205 is controlled by a control signal outputted from the operational amplifier 209.

Here, operation where the potential of the node N4 is higher than the potential (2.5V) of the node N5, and operation where the potential of the node N4 is lower than the potential (2.5V) of the node N5 will be described. First, when the potential of the node N4 is higher than the potential (2.5V) of the node N5, the operational amplifier 209 applies a control signal having a higher potential to the gate of the NMOS 205. Then, the NMOS 205 is in a stronger conductive state, and the potential of the node N2 becomes lower. The voltage between the gate and the source of the NMOS 203 becomes greater, and the NMOS 203 becomes in a stronger conductive state. As a result, the potential of the node N3 becomes lower than the potential of the node N4 which are short-circuited together. In this manner, the potential of the node N4 becomes closer to the potential of the node N5 due to the control signal outputted from the operational amplifier 209. On the other hand, when the potential of the node N4 is lower than the potential (2.5V) of the node N5, the operational amplifier 209 applies a control signal having a lower potential to the gate of the NMOS 205. Then, the NMOS 205 is in a weaker conductive state, and the potential of the node N2 becomes higher. The voltage between the gate and the source of the NMOS 203 becomes smaller, and the NMOS 203 becomes in a weaker conductive state. As a result, the potential of the node N3 becomes higher than the potential of the short-circuited node N4. In this manner, the potential of the node N4 becomes closer to the potential of the node N5 due to the control signal outputted from the operational amplifier 209. As a result of these operations, the potential of the node N4 stabilizes at 2.5V when 2.5V of the reference potential is set to the reference potential generating circuit 211.

The control signal applied to the gate of the NMOS 205 is also applied to the gate of the NMOS 109. This means that the current flowing in the NMOS 109 is twice as much as the current flowing in the NMOS 205 since the dimension of the NMOS 109 is set to twice the dimension of the NMOS 205. However, since a ratio of (2:3:4) for the dimension of the PMOS 101, the dimension of the NMOS 103, and the dimension of the NMOS 109 is set to be equal to the ratio (2:3:4) for the dimension of the PMOS 201, the dimension of the NMOS 203, and the dimension of the NMOS 205, and a ratio for the ON resistance value of the PMOS 101, the ON resistance value of the NMOS 103, and the ON resistance value of the NMOS 109 becomes equal to the ratio of the ON resistance value of the PMOS 201, the ON resistance value of the NMOS 203, and the ON resistance value of the NMOS 205. In other words, in this embodiment, since the potential of the node N3 is 2.5V, (the ON resistance value of the PMOS 101):(the total of the ON resistance value of the NMOS 103 and the ON resistance value of the NMOS 109)=(the ON resistance value of the PMOS 201):(the total of the ON resistance value of the NMOS 203 and the ON resistance value of the NMOS 205)=1:1. Therefore, if the potential of the node N4 or the threshold of the inverter INV2 is 2.5V, the threshold of the inverter INV1 is also set to 2.5V.

Next, the case where 3V is used as a power supply potential VDD is described.

When 3V is used for the power supply potential VDD, a threshold of the inverter INV1 is preferably set to 1.5V. This is because it is necessary to fully secure both a margin at the “H” side and a margin at the “L” side. When 3V is used for the power supply potential VDD, VIH is set to 2.1V (power supply potential VDD×0.7) and VIL is set to 0.9V (power supply potential VDD×0.3). As a result, these both margins can be fully secured when a threshold potential is set to 1.5V constituting an intermediate value between the VIH (2.1V) and the VIL (0.9V). Therefore, 1.5V of a reference potential is set for the reference potential generating circuit 211.

In the circuit diagram of FIG. 2, the resistive elements 213 and 215 constituting the reference potential generating circuit 211 are both set to 200 k●. Since the power supply potential node T1 is supplied with 3V of the power supply potential VDD and the earth potential node T2 is supplied with 0V of the earth potential GND, 1.5V of the reference potential is outputted from the reference potential generating circuit 211. The subsequent operation of the operational amplifier 209 is the same as in the previously described operation where 5V of the power supply potential VDD is provided, and the control signal to make the potential of the node N4 become 1.5V is stably outputted to the NMOS 205. Namely, when 3V is used for the power supply potential VDD, if the potential of the node N4 or the threshold of the inverter INV2 is 1.5V, the threshold of the inverter INV1 is also set to 1.5V, the same as in the case of using 5V of the power supply potential VDD.

FIG. 3 shows input/output waveforms of the input circuit of the first embodiment obtained by a circuit simulation. FIG. 3(a) shows simulation results when the power supply potential VDD=5V, and the earth potential GND=0V, and FIG. 3(b) shows simulation results when the power supply potential VDD=3V, and the earth potential GND=0V. Each horizontal axis of FIG. 3(a)(b) represents time, and each vertical axis represents potential.

First, simulation results when the power supply potential VDD=5V, and the earth potential GND=0V will be described. First, the solid line (1) represents the reference potential. Since the resistive elements 213 and 215 constituting the reference potential generating circuit 211 are both set to 200 kΩ, 2.5V of the reference potential is outputted from the reference potential generating circuit 211 and applied to the inverting input terminal of the operational amplifier 209. Next, the dotted line (2) represents the output signal or the control signal of the operational amplifier 209. The operational amplifier 209 applies 3.75V output signal to gates of the NMOS 109 and the NMOS 205 according to the previously described operation. In this state, the IN signal shows 5V and the OUT signal shows 0V at the time t0. When the IN signal gradually starts to fall at the time t1, the OUT signal gradually starts to rise as a result. The values of the IN signal and the OUT signal become equal at the time t2. Then, when the IN signal falls further, the OUT signal rises further, and when the IN signal reaches 0V at the time t3, the OUT signal becomes 5V. The threshold of the inverter INV1 means the potential value where the values of the IN signal and the OUT signal become equal at the time t2, and the value becomes 2.5V as a result of the simulation.

After this, when the IN signal starts to rise at the time t4, the OUT signal starts to fall as a result. The values of the IN signal and the OUT signal become equal at the time t5. The potential value at this time is the threshold of the inverter INV1, and this value also becomes 2.5V.

Next, simulation results when the power supply potential VDD=3V, and the earth potential GND=0V will be described using FIG. 3(b). First, the solid line (1) represents the reference potential. Since the resistive elements 213 and 215 constituting the reference potential generating circuit 211 are both set to 200 k●, 1.5V of the reference potential is outputted from the reference potential generating circuit 211 and applied to the inverting input terminal of the operational amplifier 209. Next, the dotted line (2) represents the output signal and the control signal of the operational amplifier 209. The operational amplifier 209 applies an output signal of 2.31V to the gates of the NMOS 109 and the NMOS 205 according to the previously mentioned operations. In this state, the IN signal is 3V and the OUT signal is 0V at the time t0. When the IN signal gradually starts to fall at the time t1, the OUT signal gradually starts to rise as a result. The values of the IN signal and the OUT signal become equal at the time t2. Then, the IN signal falls further, the OUT signal falls further as a result, and when the IN signal reaches 0V, the OUT signal becomes 3V at the time t3. The threshold of the inverter INV1 means the potential value where the values of the IN signal and the OUT signal becomes equal at the time t2, and the value becomes 1.5V as a result of the simulation.

After that, when the IN signal starts to rise at the time t4, the OUT signal starts to fall as a result. The values of the IN signal and the OUT signal become equal at the time t5. The potential value at this time is the threshold of the inverter INV1, and the value also becomes 1.5V.

As learned from the simulation results, in the first embodiment of the present invention, when 2.5V is set for the reference potential generating circuit 211 when using 5V as a power supply potential VDD, the threshold of the inverter INV1 receiving an IN signal shows 2.5V (FIG. 3(a)), and when 1.5V is set for the reference potential generating circuit 211 when using 3V as a power supply potential VDD, the threshold of the inverter INV1 receiving an IN signal shows 1.5V (FIG. 3(b)). In other words, it is necessary to reset the threshold according to the power supply potential VDD level in order to fully secure threshold margins under different power supply potentials VDD, however, by using the first embodiment of the present invention, a threshold of an inverter INV1 can be set to a desired level without changing the dimensions of transistors constituting the inverter INV1.

In this manner, according to the first embodiment of the present invention, by providing the threshold circuit 111 at the input circuit, a threshold of the inverter INV1 can be set to a desired level according to the power supply potential levels VDD. As a result, margins at the “H” side and at the “L” side of the inverter INV1 can be both fully secured, and when noise occurs on a power supply potential and an earth potential, output signals generated due to the noise exceeding the threshold of the inverter INV1 can be suppressed.

Second Embodiment

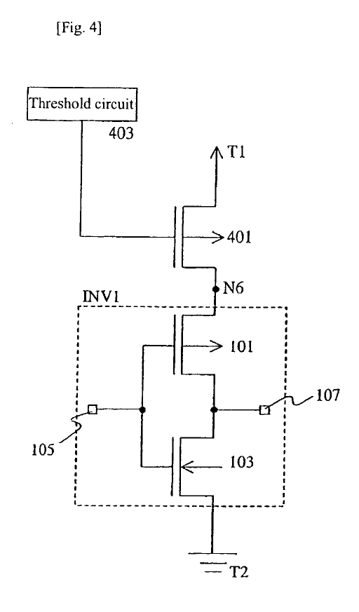

FIG. 4 shows a second embodiment of the present invention. In the second embodiment, a control signal outputted from the threshold circuit 403 is received by PMOS401 provided between a power supply potential node T1 and a node N6, rather than the control signal outputted from the threshold circuit 111 being received by the NMOS 109 provided between the earth potential node T2 and the node N2 as in the input circuit shown in FIG. 1. An input circuit shown in FIG. 4 comprises a power supply potential node T1, an earth potential node T2 (also referred to is a reference potential node T2), a node N6, a complementary type (CMOS) inverter INV1 for receiving, inverting and outputting a signal, a first conduction type MOS transistor constituting a switch circuit for conducting between the power supply potential node T1 and the node N6 in response to a control signal (here PMOS 401), and a threshold circuit 403 for detecting a power supply potential VDD and for outputting a control signal.

A power supply potential VDD is provided to the power supply potential node T1. The power supply potential VDD is 5V or 3V in this embodiment. A reference potential taken as a reference is provided to the earth potential node T2. Earth potential GND is used as the reference potential in this case. The earth potential GND is 0V in this embodiment.

The inverter INV1 comprises a first conduction type and a second conduction type MOS transistor (PMOS 101 and NMOS 103), an input node 105, and an output node 107.

A source of the PMOS 401 is connected to the power supply potential node T1 and a drain is connected to the node N6. The threshold circuit 403 is connected to a gate (a gate is defined as a control electrode at the MOS transistor) of the PMOS 401.

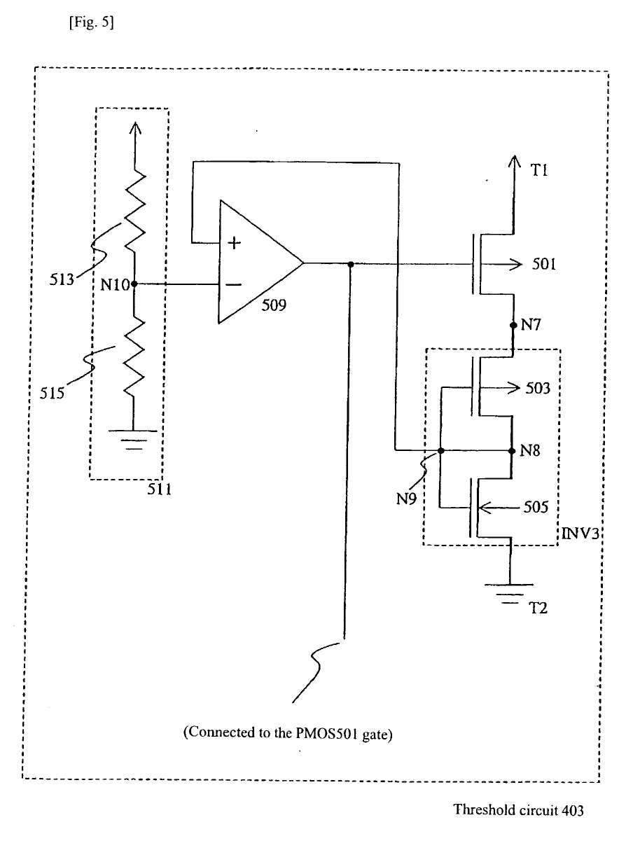

Next, the threshold circuit 403 of FIG. 4 will be described with reference to a circuit diagram of FIG. 5. The threshold circuit 403 comprises a power supply potential node T1, an earth potential node T2, a node N7, an inverter INV3 (although this is referred to as an inverter INV3, this does not actually have a function for inverting a signal because the input/output is short-circuited), a PMOS 501, a control circuit 509 (an operational amplifier is used for the control circuit in this embodiment), and a reference potential generating circuit 511 for generating a reference potential.

The inverter INV3 comprises a PMOS 503, a NMOS 505, nodes N8, N9, with a gate of the PMOS. 503 being connected to the node N9, a source being connected to the node N7, and a drain being connected to the node N8. A gate of PMOS 505 is connected to the node N9, a source is connected to the earth potential node T2, and a drain is connected to the node N8. The node N9 and the node N8 constituting an input/output node of the inverter are short-circuited together, and saturation currents I503 and I505 respectively flow to the PMOS 503 and the NMOS 505 constituting the inverter. The potential of the node N9 becomes a threshold of the inverter when these saturation currents I503 and I505 are balanced. At the PMOS 501, a source is connected to the power supply potential node T1 and a drain is connected to the node N7. A ratio of a dimension of the PMOS 501, a dimension of the NMOS 503, and a dimension of the PMOS 505 is set equal to a ratio of a dimension of the PMOS 401, a dimension of the PMOS 101, and a dimension of the NMOS 103. For example, (PMOS 501 dimension):(PMOS 503 dimension):(NMOS 505 dimension)=(PMOS 401 dimension):(PMOS 101 dimension):(NMOS 103 dimension)=2:3:4. By being set in this manner, (an ON resistance value of the PMOS 501):(an ON resistance value of the PMOS 503):(an ON resistance value of the NMOS 505) becomes equal to (an ON resistance value of the PMOS 401):(an ON resistance value of the PMOS 101):(an ON resistance value of the NMOS 103) when the same control signal is provided to the gate of the PMOS 501 and the gate of the PMOS 401. Namely, by setting in this manner, (the total of the ON resistance value of the PMOS 501 and the ON resistance value of the PMOS 503):(the ON resistance value of the NMOS 505) becomes equal to (the total of the ON resistance value of the PMOS 401 and the ON resistance value of the PMOS 101):(the ON resistance value of the NMOS 103), and a threshold of the inverter INV3 becomes equal to a threshold of the inverter INV1. By setting (the total of the ON resistance value of the PMOS 501 and the ON resistance value of the PMOS 503):(the ON resistance value of the NMOS 505)=(the total of the ON resistance value of the PMOS 401 and the ON resistance value of the PMOS 101):(the ON resistance value of the NMOS 103) to substantially 1:1, the threshold of the inverter INV3 and the threshold of the inverter INV1 become approximately half the power supply potential VDD., The ratio of substantially 1:1 exhibits the range within which the present invention is effective, and ratios such as 1.1:0.9 are therefore by no means excluded. In this embodiment, the dimension (W/L) of the PMOS 401 is set to 40 μm/2 μm, the PMOS 101 to 60 μm/2 μm, and the NMOS103 to 80 μm/2 μm, and the dimension of the PMOS 501 is set to 20 μm/2 μm, the PMOS 503 to 30 μm/2 μm, and the NM6S 505 to 40 μm/2 μm. At the operational amplifier 509, a non-inverting input terminal (+) is connected to the node N9, an inverting input terminal (−) is connected to the reference potential generating circuit 511, and an output terminal is connected to the gate of the PMOS 501 and the gate of the PMOS 401. The reference potential generating circuit 511 is, for example, a voltage divider circuit comprising a plurality of resistive elements connected in series. In FIG. 5, resistive elements 513 and 515 are connected in series, with a commonly connected end constituting a node N10. A resistance value of the resistive elements 513 and 515 will be set to 200 k●. in this embodiment. The node N10 is connected to the non-inverting input terminal of the operational amplifier 509.

Next, the operation will be described. First, a case where 5V is used for a power supply potential VDD is described.

When 5V is used for the power supply potential VDD, a threshold of the inverter INV1 is preferably set to 2.5V. This is because it is necessary to fully secure both a margin at the “H” side and a margin at the “L” side. When 5V is used for the power supply potential VDD, VIH is set to 3.5V (power supply potential VDD×0.7) and VIL is set to 1.5V (power supply potential VDD×0.3). As a result, both of these margins can be fully ensured when a threshold potential is set to 2.5V constituting an intermediate value between the VIH (3.5V) and the VIL (1.5V). Therefore, a reference potential of 2.5V is set for the reference potential generating circuit 511.

In the circuit diagram of FIG. 5, the resistive elements 513 and 515 constituting the reference potential generating circuit 511 are both set to 200 kΩ. Since the power supply potential node T1 is supplied with 5V of the power supply potential VDD and the earth potential node T2 is supplied with 0V of the earth potential GND, a reference potential of 2.5V is outputted from the reference potential generating circuit 511.

At the operational amplifier 509, a reference potential of 2.5V outputted from the reference potential generating circuit 511 is received at the inverting input terminal, the potential of the node N9 is received at the non-inverting input terminal, and the result of comparing these voltages is outputted to the PMOS 501. In the circuit configuration of FIG. 5, when the potential of the node N10 is 2.5V, the operational amplifier 509 outputs a control signal to the PMOS 501 so that the potential of the node N9 also becomes 2.5V.

This operation will now be described in detail. The node N9 and the node N8 constituting an input/output node of the inverter INV3 are short-circuited together, and saturation currents I503 and I505 respectively flow to the PMOS 503 and the NMOS 505 constituting the inverter INV3. The potential of the node N9 becomes a threshold of the inverter INV3 when these saturation currents I503 and I505 are balanced. At this time, since the saturation current I503 flowing in the PMOS 503 that constitutes the inverter INV3 flows from the PMOS 501, the saturation current I503 becomes equal to a current I501 flowing into the PMOS 501. Therefore, the threshold of the inverter INV3 is determined by the current I501 flowing into the PMOS 501, and the current I501 is determined by a voltage between the gate and the source of the PMOS 501. The gate potential of the PMOS 501 is controlled by a control signal outputted from the operational amplifier 509.

Here, the operation where the potential of the node N9 is higher than the potential (2.5V) of the node N10, and the operation where the potential of the node N9 is lower than the potential (2.5V) of the node N10 will be described. First, when the potential of the node N9 is higher than the potential (2.5V) of the node N10, the operational amplifier 509 applies a control signal having a higher potential to the gate of the PMOS 501. Then, the PMOS 501 is in a weaker conductive state, and the potential of the node N7 becomes lower. The voltage between the gate and the source of the PMOS 503 becomes smaller, and the PMOS 503 becomes in a weaker conductive state. As a result, the potential of the node N8 becomes lower than the potential of the short-circuited node N9. In this manner, the potential of the node N9 becomes closer to the potential of the node N10 due to the control signal outputted from the operational amplifier 509. On the other hand, when the potential of the node N9 is lower than the potential (2.5V) of the node N10, the operational amplifier 509 applies a control signal having a lower potential to the gate of the PMOS 501. Then, the PMOS 501 is in a stronger conductive state, and the potential of the node N7 becomes higher. The voltage between the gate and the source of the PMOS 503 becomes greater, and the NMOS 203 enters a stronger conductive state. As a result, the potential of the node N8 becomes higher than the potential of the short-circuited node N9. In this manner, the potential of the node N9 becomes closer to the potential of the node N10 by the control signal outputted from the operational amplifier 509. By these operations, also the potential of the node N9 stabilizes at 2.5V when 2.5V of the reference potential is set for the reference potential generating circuit 511.

The control signal applied to the gate of the PMOS 501 is also applied to the gate of the PMOS 401. This means that the current flowing in the PMOS 401 is twice as much as the current flowing in the PMOS 501 since the dimension of the PMOS 401 is set to twice that of the PMOS 501. However, since the ratio (2:3:4) of the dimension of the PMOS 401, the dimension of the PMOS 101, and the dimension of the NMOS 103 is set equal to the ratio (2:3:4) of the dimension of the PMOS 501, the dimension of the PMOS 503, and the dimension of the NMOS 505, the ratio of the ON resistance value of the PMOS 401, the ON resistance value of the PMOS 101, and the ON resistance value of the NMOS 103 becomes equal to the ratio of the ON resistance value of the PMOS 501, the ON resistance value of the PMOS 503, and the ON resistance value of the NMOS 505. In other words, in this embodiment, since the potential of the node N8 is 2.5V, (the total of the ON resistance value of the PMOS 401 and the ON resistance value of the PMOS 101):(the ON resistance value of the NMOS 103)=(the total of the ON resistance value of the PMOS 501 and the ON resistance value of the PMOS 503):(the ON resistance value of the NMOS 505)=1:1. Therefore, if the potential of the node N9 or the threshold of the inverter INV3 is 2.5V, the threshold of the inverter INV1 is also set to 2.5V.

Next, a case where 3V is used for a power supply potential VDD is described.

When 3V is used for the power supply potential VDD, a threshold of the inverter INV1 is preferably set to 2.5V. This is because it is necessary to fully secure both a margin at the “H” side and a margin at the “L” side. When 3V is used for the power supply potential VDD, VIH is set to 2.1V (power supply potential VDD×0.7) and VIL is set to 0.9V (power supply potential VDD×0.3). As a result, both these margins can be fully secured when a threshold potential is set to 1.5V constituting an intermediate value between the VIH (2.1V) and the VIL (0.9V). Therefore, 1.5V of a reference potential is set for the reference potential generating circuit 511.

In the circuit diagram of FIG. 5, the resistive elements 513 and 515 constituting the reference potential generating circuit 511 are both set to 200 k●. Since the power supply potential node T1 is supplied with 3V of the power supply potential VDD and the earth potential node T2 is supplied with 0V of the earth potential GND, 1.5V of the reference potential is outputted from the reference potential generating circuit 511. The subsequent operations of the operational amplifier 509 are the same as in the previously described operations where 5V of the power supply potential VDD is provided, and a signal where the potential of the node N9 becomes 1.5V is stably outputted to the gate of the PMOS 501. Namely, when 3V is used for the power supply potential VDD, if the potential of the node N9 or the threshold of the inverter INV3 is 1.5V, the threshold of the inverter INV1 is also set to 1.5V, as with the case of using 5V of the power supply potential VDD.

In this manner, according to the second embodiment of the present invention, by providing the threshold circuit 403 at the input circuit, a threshold of the inverter INV1 can be set to a desired level according to power supply potential levels VDD. As a result, margins at the “H” side and at the “L” side of the inverter INV1 can be both fully secured, and when noise occurs on a power supply potential and an earth potential, the generation of output signals due to the noise exceeding the threshold of the inverter INV1 can be suppressed.

Third Embodiment

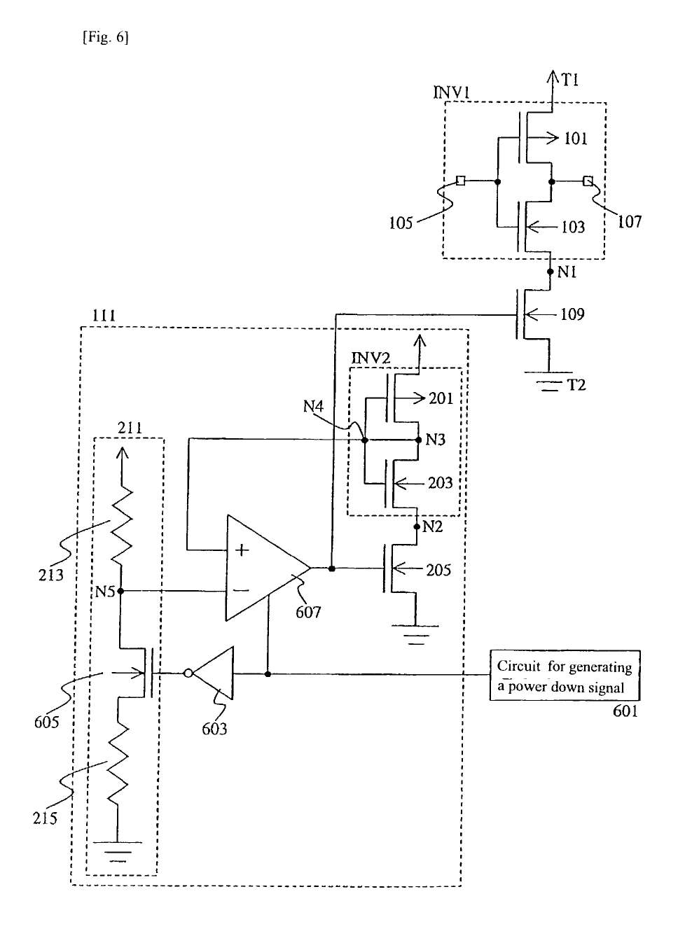

FIG. 6 shows a third embodiment of the present invention. A description is given in the following giving the same numerals to portions that are the same as for the input circuit of the first embodiment shown in FIG. 1 and FIG. 2.

Differences from the first embodiment are that a power signal generating circuit 601, an inverter 603, an NMOS 605 and a control circuit (in this embodiment an operational amplifier is used as the control circuit) 607 are provided. The power signal generating circuit 601 is connected to the inverter 603 and the control circuit 607, generates an “H” level signal during powering down, and generates an “L” level signal during normal operation. “Powering down” refers to when an integrated circuit is put into a non-active state. An input terminal of the inverter 603 is connected to the power signal generating circuit 601, and an output terminal is connected to a gate of NMOS 605, with the inverter 603 receiving a power down signal, inverting and then outputting this signal. The source of NMOS 605 is connected to resistance element 215 and the drain is connected to node N5. The NMOS 605 is set to receive an “H” signal inverted by the inverter 603 and enter an “ON” state when a power down signal of “L” is outputted from the power signal generating circuit 601. On the other hand, the NMOS 605 is set to receive an “L” signal inverted by the inverter 603 and enter an “OFF” state when a power down signal of “H” is outputted from the power signal generating circuit 601. The control circuit 607 is connected to the power signal generating circuit 601 and is set to be in a normal operating state when an “L” power down signal is received, and is set to an off state and to output a prescribed potential (for example, ground potential GND) when an “H” level power down signal is received.

Next, a description is given of the operation.

First, a description is given of the operation of the input circuit during normal operation. An “L” level power down signal is outputted from the power signal generating circuit 601 during normal operation. The NMOS 605 is set to receive an “H” signal inverted by the inverter 603 and enter an “ON” state. The control circuit 607 is set to be in an “ON” state upon receiving an “L” level power down signal. The operation of the input circuit is then the same as the operation of the input circuit of the first embodiment.

First, a description is given of the operation of the input circuit during normal operation

An “H” level power down signal is outputted from the power signal generating circuit 601 during powering down. The “H” level power down signal is then inverted by the inverter 603 to become an “L” level signal, which is then applied to the gate of NMOS 605 constituting the reference potential generating circuit 211. As a result, the NMOS 605 is set to an “OFF” state, and a current transmitting path between the power supply potential node T1 and the earth potential node T2 is interrupted. In this embodiment, this state of the reference potential generating circuit 211 is referred to as an “OFF” state.

The control circuit 607 receiving this “H” level power down signal is then set to an “OFF” state, and a signal of a level of the earth potential GND is outputted.

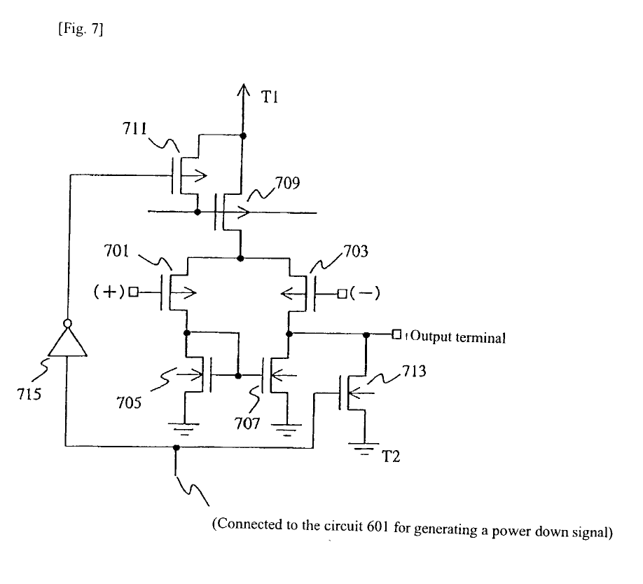

A detailed description will now be given regarding the control circuit 607. FIG. 7 is a circuit diagram showing the control circuit 607. The control circuit 607 is comprised of a PMOS's 701, 703, 709 and 711, NMOS's 705, 707 and 713, and an inverter 715. The gate of the PMOS 701 is connected to the non-inverting input terminal (+) and the gate of the PMOS 703 is connected to the inverting terminal (−). The sources of the PMOS's 701 and 703 are connected to the drain of PMOS 709, a bias potential is supplied to the gate of PMOS709, and the source of PMOS 709 is connected to power supply potential node T1. The source of PMOS711 is connected to power supply potential node T1, the drain is connected to the gate of PMOS 709, and the gate is connected to the output terminal of inverter 715. The input terminal of the inverter 715 is connected to the power signal generating circuit 601. The gates of NMOS's 705 and 707 are connected to the drain of NMOS705, and the sources of NMOS 705 and NMOS 707 are connected to earth potential node T2. The drain of NMOS 705 is connected to the drain of PMOS 701 and the drain of NMOS 707 is connected to the drain and output terminal of PMOS 703. The source of AMOS 713 is connected to earth potential node T2, the drain is connected to the output terminal, and the gate is connected to the power signal generating circuit 601.

A detailed description will now be given regarding the operation of the control circuit 607. The “H” level power down signal outputted from the power signal generating circuit 601 is inverted by the inverter 715 and applied to the gate of PMOS 711 as an “L” level signal. The PMOS 711 receiving the “L” level signal then goes “ON”. As a result, the PMOS 709 goes “ON” as a result of the power supply potential VDD supplied to the power supply potential node T1 being applied to the gate of PMOS 709 connected between the power supply potential node T1 and the sources of PMOS 701 and PMOS 703 via PMOS 711. As a result, a current transmitting path between the power supply potential node T1 at the control circuit 607 and the earth potential node T2 is interrupted. The “H” level power down signal outputted from the power signal generating circuit 601 is applied to the NMOS 713 and NMOS 713 is set to an “ON” state. As a result, the output terminal of the control circuit 607 is set to a level of ground potential GND via NMOS 713.

A signal the level of ground potential outputted from the control circuit 607 is applied to the gate of the NMOS 205 and the NMOS 205 is set to OFF. As a result, a current transmitting path between the power supply potential node T1 at the inverter INV2 and the earth potential node T2 is interrupted. A signal the level of ground potential is applied to the gate of the NMOS 10901 and the NMOS 109 is set to OFF. A current transmitting path between the power supply potential node T1 at the inverter INV1 and the earth potential node T2 is therefore interrupted.

According to the present invention as laid out in the third embodiment, as with the first embodiment, in addition to it being possible to guarantee a sufficient margin for both the “H” side margin and the “L” side margin, it is also possible to interrupt a current transmission path between the power supply potential node T1 occurring at the control circuit 607, inverters INV1 and INV2 and the reference potential generating circuit 111 and the earth potential node T2. As a result, it is possible to prevent through-current from flowing at the control circuit 607, inverters INV1 and INV2, and the reference potential generating circuit 111 when the integrated circuit is in a non-active state.

Fourth Embodiment

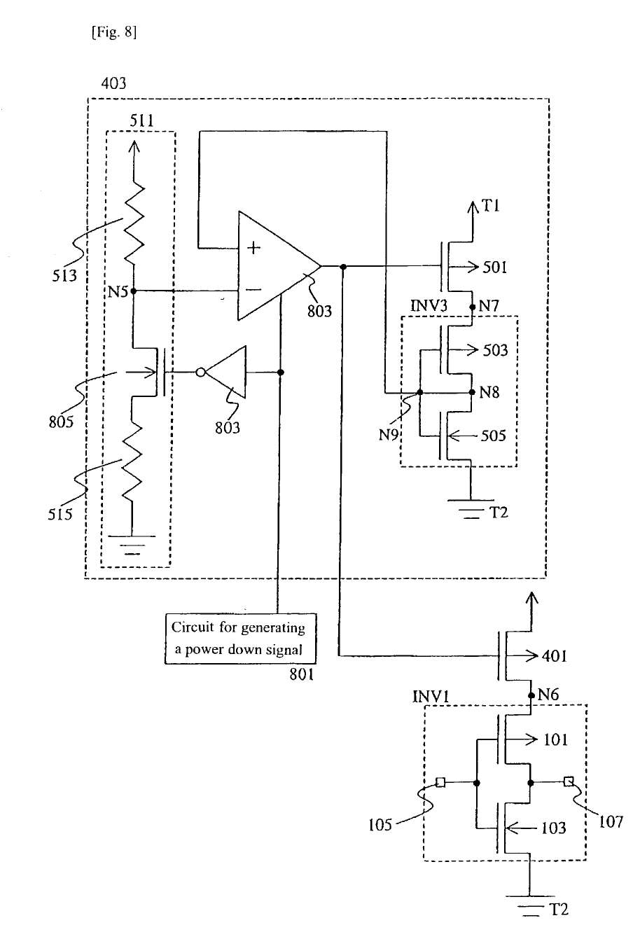

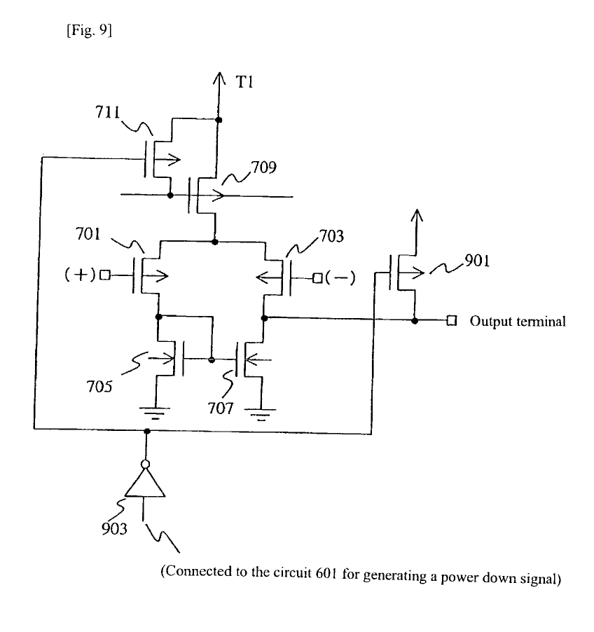

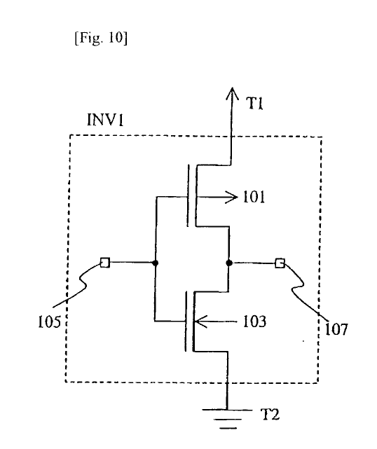

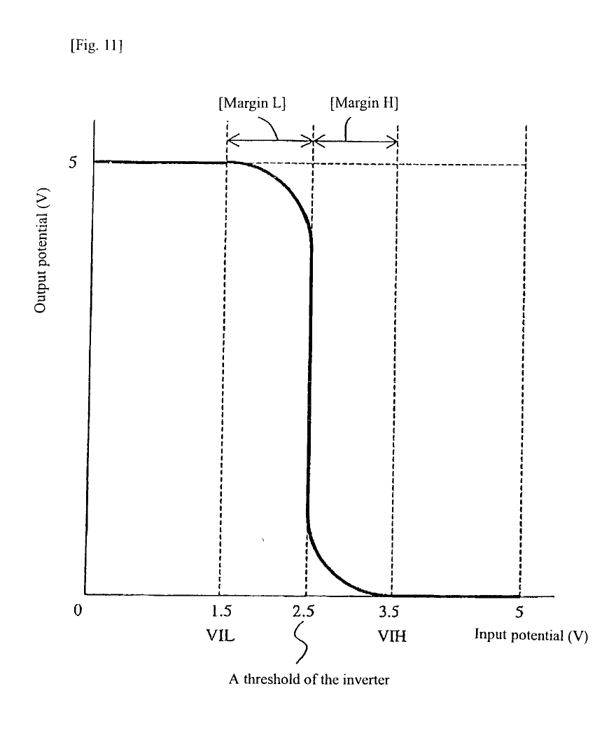

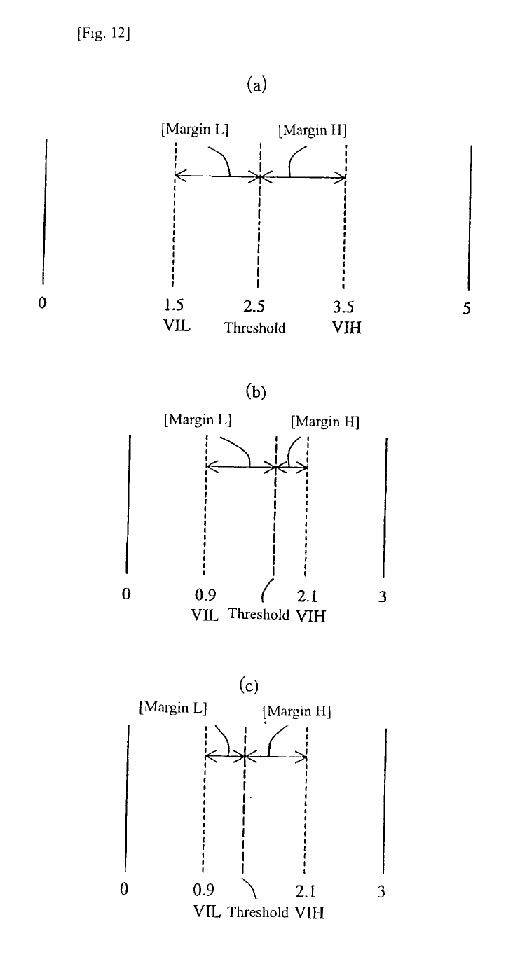

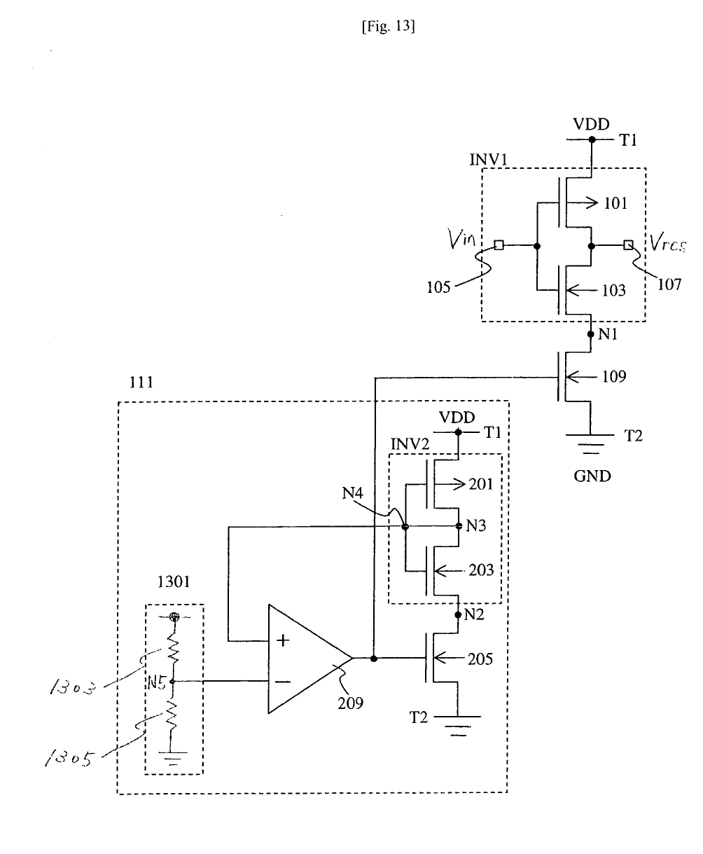

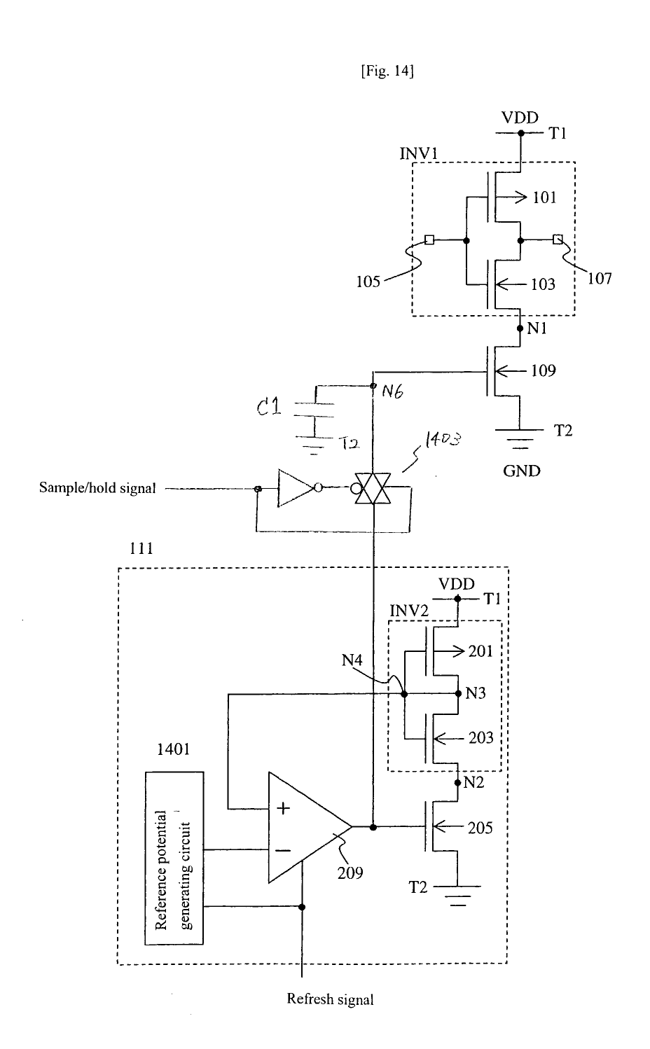

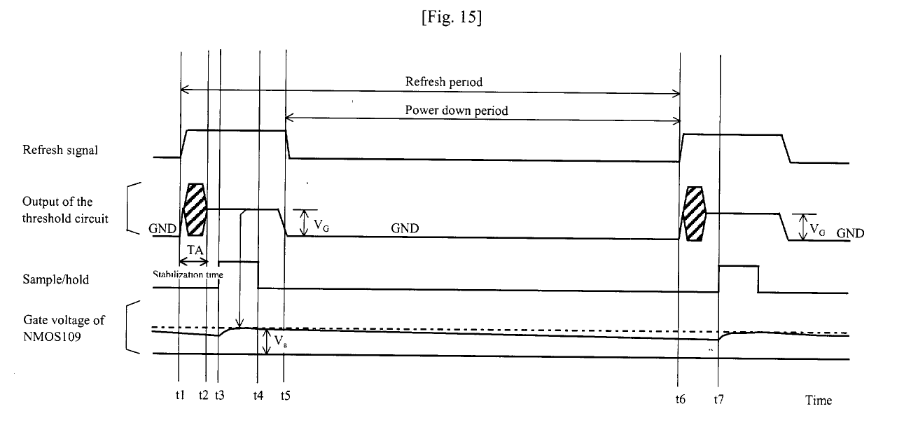

A fourth embodiment of the present invention is shown in FIG. 8. Differences from the second embodiment shown in FIG. 4 and FIG. 5 are that a power signal generating circuit 801, an inverter 803, an NMOS 805 and a control circuit (in this embodiment an operational amplifier is used as the control circuit) 807 are provided. The power signal generating circuit 801 is connected to the inverter 803 and the control circuit 807, generates an “H” level signal during powering down, and generates an “L” level signal during normal operation. “Powering down” refers to when an integrated circuit is put into a non-active state. An input terminal of the inverter 803 is connected to the power signal generating circuit 801, and an output terminal is connected to a gate of NMOS 805, with the inverter 803 receiving a power down signal, inverting and then outputting this signal. The source of NMOS 805 is connected to resistance element 515 and the drain is connected to node N10. The NMOS 805 is set to receive an “H” signal inverted by the inverter 803 and enter an “ON” state when a power down signal of “L” is outputted from the power signal generating circuit 801. On the other hand, the NMOS 805 is set to receive an “L” signal inverted by the inverter 803 and enter an “OFF” state when a power down signal of “H” is outputted from the power signal generating circuit 801. The control circuit 807 is connected to the power signal generating circuit 801 and is set to be in a normal operating state when an “L” power down signal is received, and is set to an off state and to output a prescribed potential (for example, ground potential GND) when an “H” level power down signal is received.

Next, a description is given of the operation.

First, a description is given of the operation of the input circuit during normal operation. An “L” lever power down signal is outputted from the power signal generating circuit 801 during normal operation. The NMOS 805 is set to receive an “H” signal inverted by the inverter 803 and enter an “ON” state. The control circuit 807 is set to be in an “ON” state upon receiving an “L” level power down signal. The operation of the input circuit is then the same as the operation of the input circuit of the second embodiment.

First, a description is given of the operation of the input circuit during normal operation.

An “H” level power down signal is outputted from the power signal generating circuit 801 during powering down. The “H” level power down signal is then inverted by the inverter 803 to become an “L” level signal, which is then applied to the gate of NMOS 805 constituting the reference potential generating circuit 211. As a result, the NMOS 805 is set to an “OFF” state, and a current transmitting path between the power supply potential node T1 of the reference potential generating circuit 511 and the earth potential node T2 is interrupted. In this embodiment, this state of the reference potential generating circuit 511 is referred to as an “OFF” state.

The control circuit 807 receiving this “H” level power down signal is then set to an “OFF” state, and a signal of a level of the earth potential GND is outputted.

A detailed description will now be given regarding the control circuit 807. FIG. 9 is a circuit diagram showing the control circuit 807. The control circuit 801 is comprised of a PMOS's 701, 703, 709, 711 and 901, NMOS's 705 and 707, and an inverter 903. The difference with the control circuit 607 shown in FIG. 7 is that PMOS 901 and the inverter 903 are provided. The source of PMOS 901 is connected to power supply potential node T1 and the drain is connected to the output terminal, with a conducting state being controlled in response to a signal outputted from inverter 903. An input terminal of the inverter 903 is connected to the power signal generating circuit 601, and an output terminal is connected to a gate of PMOS 901 and the gate of PMOS 711.

A detailed description will now be given regarding the operation of the control circuit 801. The “H” level power down signal outputted from the power signal generating circuit 801 is inverted by the inverter 903 and applied to the gate of PMOS 711 as an “L” level signal. The PMOS 711 receiving the “L” level signal then goes “ON”. As a result, the PMOS 709 goes “ON” as a result of the power supply potential VDD supplied to the power supply potential node T1 being applied to the gate of PMOS 709 connected between the power supply potential node T1 and the sources of PMOS 701 and PMOS 703 via PMOS 711. As a result, a current transmitting path between the power supply potential node T1 at the control circuit 807 and the earth potential node T2 is interrupted. The “H” level power down signal outputted from the power signal generating circuit 801 is inverted by the inverter 903 and applied to the gate of PMOS 901 as an “L” level signal, and the PMOS 901 is set to an “ON” state. As a result, the output terminal of the control circuit 801 is fixed at the power supply potential VDD via PMOS 901.

A signal the level of ground potential outputted from the control circuit 801 is applied to the gate of the NMOS 501 and the NMOS 501 is set to OFF. As a result, a current transmitting path between the power supply potential node T1 at the inverter INV3 and the earth potential node T2 is interrupted. Further, a signal the level of power supply potential VDD is applied to the gate of the PMOS 401 and the PMOS 401 is set to OFF. As a result, a current transmitting path between the power supply potential node T1 at the inverter INV1 and the earth potential node T2 is interrupted.

According to the present invention as laid out in the fourth embodiment, as with the second embodiment, in addition to it being possible to guarantee a sufficient margin for both the “H” side margin and the “L” side margin, it is also possible to interrupt a current transmission path between the power supply potential node T1 occurring at the control circuit 807, inverters INV1 and INV2 and the reference potential generating circuit 511 and the earth potential node T2. As a result, it is possible to prevent through-current from flowing at the control circuit 807, inverters INV1 and INV3, and the reference potential generating circuit 511 when the integrated circuit is in a non-active state.

As described in detail above, according to that typifying the present invention, an inverter threshold value can be set to a prescribed level according to a power supply potential by providing a third transistor connected in series with an inverter, and a threshold circuit so as to provide input circuits capable of ensuring sufficient threshold margin when different power supply potentials are supplied.

What is claimed is:

1. An input circuit, comprising: a power supply potential node being supplied with a power supply potential;
a reference potential node being supplied with a reference potential;
an inverter connected across the power supply potential node and the reference potential node, and including a first transistor of a first conduction type and a second transistor of a second conduction type;
a third transistor of the first conduction type connected in series with the inverter between the power supply potential node and the reference potential node, and having a conducting state controlled according to a control signal; and
a threshold circuit for outputting the control signal according to the power supply potential provided to the power supply potential node.

2. The input circuit of claim 1, the threshold circuit comprising; a first node;
a first circuit, having a fourth transistor of the first conduction type including a first electrode, a second electrode and a control electrode connected to the first node, and a fifth transistor of the second conduction type including a first electrode, a second electrode and a control electrode connected to the first node, and being connected across the power supply potential node and the reference potential node;
a sixth transistor of the first conduction type being connected in series to the first circuit across the power supply potential node and the reference potential node, and having a conducting state controlled according to the control signal;
a reference potential generating circuit for generating a reference potential; and
an operational amplifier including a first input terminal connected to the first node, a second input terminal being inputted with the reference potential, and an output terminal outputting the control signal;
wherein ratios for a dimension of the fourth transistor, a dimension of the fifth transistor, and a dimension of the sixth transistor are set be equal to ratios for a dimension of the first transistor, a dimension of the second transistor, and a dimension of the third transistor.

3. An input circuit, comprising a power supply potential node supplied with a power supply potential,
a reference potential node being supplied with a reference potential,
a first node,
an inverter, having a first transistor of a first conduction type including an input node, an output node, a first electrode connected to the power supply potential node, a second electrode connected to the output node, and a control electrode connected to the input node, and a second transistor of a second conduction type including the first electrode connected to the first node, the second electrode connected to the output node, and the control electrode connected to the input node,
a third transistor of the second conduction type, having the first electrode connected to the reference potential node, the second electrode connected to the first node, and the control electrode, and
a threshold circuit for outputting a control signal for controlling a threshold of the inverter to the control electrode of the third transistor according to the power supply potential provided to the power supply potential node.

4. The input circuit of claim 3, wherein the threshold circuit outputs the control signal in such a manner that a ratio of an ON resistance value of the first transistor to the total of an ON resistance value of the second transistor and an ON resistance value of the third transistor is made to be a prescribed value.

5. The input circuit of claim 4, wherein the prescribed value is substantially 1:1.

6. The input circuit of claim 3, the threshold circuit comprising; a second node;
a third node;
a fourth node;
a fourth transistor of the first conduction type, having the first electrode connected to the power supply potential node, the second electrode connected to the third node, and the control electrode connected to the fourth node;
a fifth transistor of the second conduction type, having the first electrode connected to the second node, the second electrode connected to the third node, and the control electrode connected to the fourth node;
a sixth transistor of the second conduction type, having the first electrode connected to the reference potential node, the second electrode connected to the second node, and the control electrode;
a control circuit for outputting the control signal to the control electrode of the third transistor and the control electrode of the sixth transistor; and
a reference potential generating circuit for generating a reference potential;
wherein the third node and the fourth node are connected;
a ratio of a dimension of the fourth transistor, a dimension of the fifth transistor, and a dimension of the sixth transistor, is set equal to a ratio of a dimension of the first transistor, a dimension of the second transistor, and a dimension of the third transistor;
and the control circuit outputs the control signal in such a manner that a potential level of the fourth node is equal to a level of the reference potential.

7. The input circuit of claim 6, wherein a ratio for a dimension of the fourth transistor, a dimension of the fifth transistor, and a dimension of the sixth transistor, is set equal to a ratio for a dimension of the first transistor, a dimension of the second transistor, and a dimension of the third transistor.

8. The input circuit of claim 6 or claim 7, the control circuit comprising an operational amplifier having a first input terminal connected to the fourth node, a second input terminal connected to the reference potential generating circuit, and an output terminal for outputting the control signal.

9. An input circuit, comprising a power supply potential node being supplied with a power supply potential;
a reference potential node being supplied with a reference potential;
a first node;
a first transistor of a first conduction type having a first electrode connected to the power supply potential node, a second electrode connected to the first node, and a control electrode;
an inverter, having a second transistor of the first conduction type including an input node, an output node, the first electrode connected to the first node, a second electrode connected to the output node, and a control electrode connected to the input node, and a third transistor of a second conduction type including the first electrode connected to the reference potential node, the second electrode connected to the output node, and the control electrode connected to the input node; and
a threshold circuit for outputting a control signal for controlling a threshold of the inverter to the control electrode of the first transistor according to the power supply potential provided to the power supply potential node.

10. The input circuit of the claim 9, wherein the threshold circuit outputs the control signal in such a manner that a ratio of the total of an ON resistance value of the first transistor and an ON resistance value of the second transistor to an ON resistance value of the third transistor is made to be a prescribed value.

11. The input circuit of the claim 10, wherein the prescribed value is substantially 1:1

12. The input circuit of claim 9, the threshold circuit comprising; a second node;
a third node;
a fourth node;
a fourth transistor of the first conduction type, having the first electrode connected to the power supply potential node, the second electrode connected to the second node, and the control electrode;
a fifth transistor of the first conduction type, having the first electrode connected to the second node, the second electrode connected to the third node, and the control electrode connected to the fourth node;
a sixth transistor of the second conduction type, having the first electrode connected to the reference potential node, the second electrode connected to the third node, and the control electrode connected to the fourth node;
a control circuit for outputting the control signal to the control electrode of the first transistor and the control electrode of the fourth transistor; and
a reference potential generating circuit for generating a reference potential;
wherein the third node and the fourth node are connected;
a ratio of a dimension of the fourth transistor, a dimension of the fifth transistor, and a dimension of the sixth transistor, is set to be equal to a ratio of a dimension of the first transistor, a dimension of the second transistor, and a dimension of the third transistor;
and the control circuit outputs the control signal in such a manner that a potential level of the fourth node is equal to a level of the reference potential.

13. The input circuit of claim 12, wherein a ratio of a gate width of the fourth transistor, a gate width of the fifth transistor, and a gate width of the sixth transistor is equal to a ratio of a gate width of the first transistor, a gate width of the second transistor, and a gate width of the third transistor.

14. The input circuit of claim 12 or claim 13, the control circuit comprising an operational amplifier having a first input terminal connected to the fourth node, a second input terminal connected to the reference potential generating circuit, and an output terminal for outputting the control signal.

15. The input circuit of any of Claims from 6 to 8, wherein the reference potential generating circuit is set to OFF in response to a power-down signal.

16. The input circuit of any of claims 12 to 14, wherein the reference potential generating circuit is set to OFF in response to a power-down signal.

17. The input circuit of claim 6 or 7, wherein the control circuit is set to OFF in response to a power-down signal and outputs a prescribed potential.

18. The input circuit of claim 8, wherein the operational amplifier is set to OFF in response to a power-down signal and outputs a prescribed potential.

19. The input circuit of claim 17 or 18, wherein the prescribed potential is the reference potential.

20. The input circuit of claim 12 or 13, wherein the control circuit is set to OFF in response to a power-down signal and outputs a prescribed potential.

21. The input circuit of claim 14, wherein the operational amplifier is set to OFF in response to a power-down signal and outputs a prescribed potential.

22. The input circuit of claim 20 or 21, wherein the prescribed potential is the power supply potential.
